(19) United States
(12) Patent Application Publication
(10) Pub. No.: US 2005/0135048 A1
(43) Pub. Date: Jun. 23, 2005

(54) COOLING MODULE OF COMPUTER SYSTEM AND RELATED APPARATUS WITH AIR WALL FOR PREVENTING RECYCLING OF HEATED AIR

(76) Inventors: Hsien-Chin Chiang, Taipei Hsien (TW); Cheng-Pang Wang, Taipei Hsien (TW)

Correspondence Address: NORTH AMERICA INTERNATIONAL PATENT OFFICE (NAIPC), P.O. BOX 506, MERRIFIELD, VA, 22116, US

(21) Appl. No.: 10/709,202

(22) Filed: Apr. 21, 2004

(30) Foreign Application Priority Data
Dec. 22, 2003 (TW) 092222397

(51) Int. Cl. H05K 7/20

(52) U.S. Cl. 361/683

(57) ABSTRACT

A cooling module for a computer system has a fan module, a heat sink module and an air wall. The heat sink module is connected to a circuit of the computer system for conducting heat generated by the circuit. The fan module makes air flow from an air inlet of the fan to the heat sink module where air absorbs heat generated by the circuit, and flow out from an air outlet of the heat sink module. The air wall is set between the air inlet of the fan and the air outlet of the heat sink module for isolating airflow from the air outlet of the heat sink module to the air inlet of the fan, such that heated air from the air outlet of the heat sink module will not significantly flow into the air inlet of the fan, and cooling efficient is therefore increased.

### BACKGROUND OF INVENTION

1. Field of the Invention

The present invention provides a cooling module of a computer system and related apparatus, and more particularly, a cooling module with an air wall preventing heated air from being recycled.

2. Description of the Prior Art

Computers have become the most important information hardware of modern times. The higher the processing speed, the higher the temperature in a computer system (especially from heat generated by a central processing unit—CPU). Only if heat of the computer system can be effectively dissipated, can the computer system operate properly and stably. Therefore, how to increase efficiency of heat dissipation in the computer system becomes one of the most important issues for development in modern information technology.

Please refer to FIG. 1, which illustrates a prior art air-cooled cooling module 20 of a computer system 10. Circuits of the computer system 10 are set in a motherboard 12. The cooling module 20 is attached to a circuit 14 (such as a chip, or a CPU) of the motherboard 12 for heat dissipation. The cooling module 20 includes a fan module 16 and a heat sink module 18. An electric fan of the fan module 16 draws air from an air inlet 22A and exhausts air from an air outlet 22B. The heat sink module 18 includes a plurality of radiator fins 28, wherein above the radiator fins 28 is an air inlet 24A, beside is an air outlet 24B, below is the circuit 14, and between each radiator fin 28 is an airway. The fan module 16 is located on the heat sink module 18, so that the air inlet 24A of the heat sink module 18 corresponds to the air outlet 22B of the fan module 16.

Operations of the cooling module 20 are as follows. In the heat sink module 18, the radiator fins 28 absorb heat from the circuit 14, conduct heat along the length of the fin. The fan module 16 draws air along an arrow 26A in FIG. 1, and blows air through the air outlet 22B of the fan module 16 into the air inlet 24A of the heat sink module 18. Then, as an arrow 26B illustrates in FIG. 1, air is exhausted from the air outlet 24B of the heat sink module 18. Therefore, as air flows from the air inlet 24A to the air outlet 24B, heat is exhausted from the radiator fins 28. With heated air exhausting from the air outlet 24B, heat provided by the circuit 14 can be dissipated.

As mentioned above, in an air-cooled cooling module, the lower the temperature of air flowing into a fan module, the higher the efficiency of heat dissipation in a heat sink module. However, as an arrow 26C in FIG. 1 illustrates, the fan module 16 can draw in air provided by the air outlet 24B, thereby recycling already heated air. With heated air cycling between the fan module 16 and the heat sink module 18, heat dissipation efficiency of the cooling module 20 is decreased seriously. Moreover, in modern computer systems, the fan module 16 of the prior art cooling module 20 increases airflow with a higher rotational speed motor, resulting in the fan module 16 drawing in much more heated air from the air outlet 24B decreasing efficiency.

### SUMMARY OF INVENTION

It is therefore a primary objective of the claimed invention to provide a cooling module with an air wall, which prevents heated air provided by a heat sink module from flowing into an air inlet of a fan module of the cooling module, so as to increase heat dissipation efficiency of the heat sink module.

Briefly described, a cooling module of a computer system includes: a fan module, a heat sink module, and an air wall. The fan module having an air inlet and an air outlet is capable of drawing air into the air inlet and exhausting air from the air outlet. The heat sink module includes an air inlet, an air outlet, and a heat conduction part. The heat conduction part is between the air inlet and the air outlet and connects to a circuit of the computer system. The air inlet connects to the air outlet of the fan module. Moreover, the heat sink module is capable of drawing air into the air inlet and through the heat conduction part to exhaust air from the air outlet. The air wall is located between the air inlet of the fan module and the air outlet of the heat sink module for isolating airflow from the air outlet of the heat sink module to the air inlet of the fan module, so that heated air from the air outlet of the heat sink module is prevented from flowing into the air inlet of the fan module.

These and other objectives of the claimed invention will no doubt become obvious to those of ordinary skill in the art after reading the following detailed description of the preferred embodiment that is illustrated in the various figures and drawings.

### BRIEF DESCRIPTION OF DRAWINGS

FIG. 1 illustrates a perspective diagram of a prior art cooling module in a computer system.

FIG. 2 illustrates a perspective diagram of the present invention cooling module.

FIG. 3 and FIG. 4 illustrate perspective diagrams of the cooling module in FIG. 2 when being installed into a computer system.

FIG. 5 illustrates a cross-sectional view of the computer system in FIG. 3.

FIG. 6 illustrates a perspective diagram of the computer system in FIG. 4 when adding an extra fan module.

FIG. 7 to FIG. 9 illustrates different implementations of fixing the air wall to the computer system in FIG. 2.

FIG. 10 illustrates a perspective diagram of the air wall in FIG. 2 when being set in a brace.

FIG. 11 and FIG. 12 illustrate the brace with the air wall when being set into the computer system in FIG. 10.

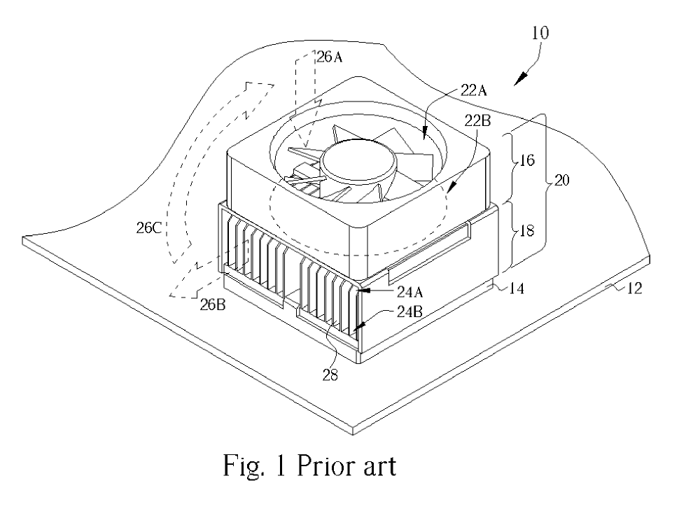

### DETAILED DESCRIPTION

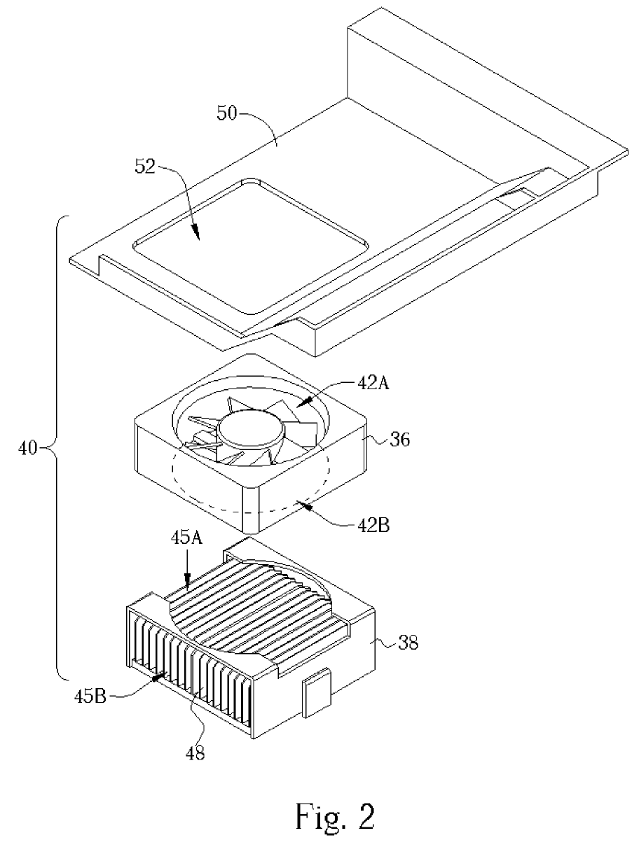

Please refer to FIG. 2, which illustrates a present invention cooling module 40. The cooling module 40 includes a fan module 36, a heat sink module 38, and an air wall 50. The fan module 36 includes an electric fan that draws air into an air inlet 42A and exhausts air from an air outlet 42B. The heat sink module 38 includes a plurality of radiator fins 48 for heat conduction; among the radiator fins 48 are an air inlet 45A and an air outlet 45B. The fan module 36 is disposed on the heat sink module 38 and blows air into the heat sink module 38 through the air inlet 45A to each radiator fin 48, heated air being exhausted from the air outlet 45B. The cooling module 40 further includes an air wall 50 for isolating airflow from the air outlet 45B to the air inlet 42A, so that air from the air outlet 45B is prevented from being recycled into the air inlet 42A. As shown in FIG. 2, the air wall 50 includes an approach 52, which matches the sizes of the air outlet 42B and the air inlet 45A. The air wall 50 prevents heated air provided by the heat sink module 38 from flowing into the air inlet 42A, preventing air from being recycled into the fan module 36.

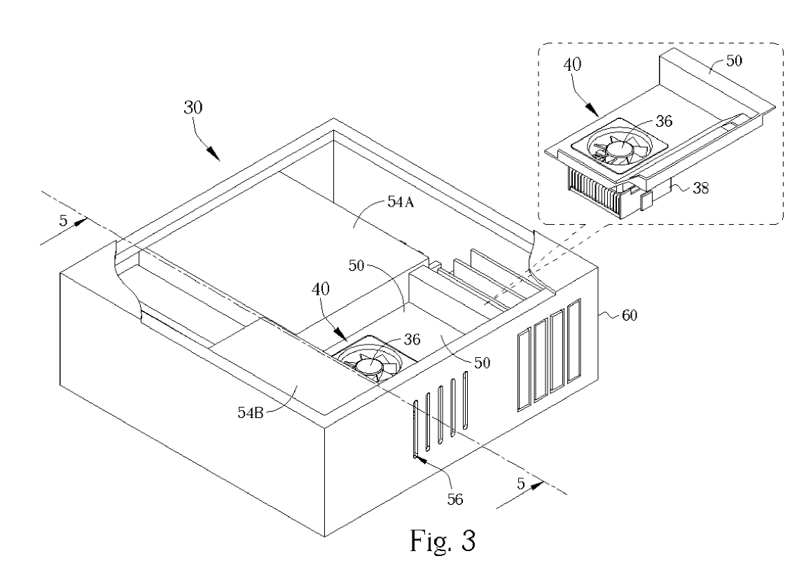

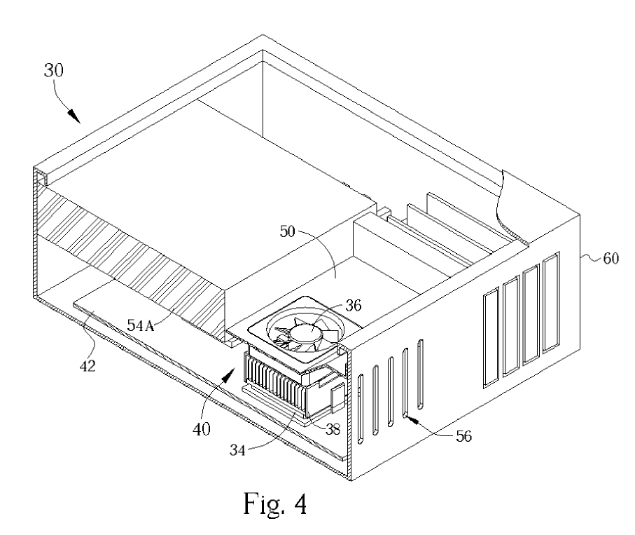

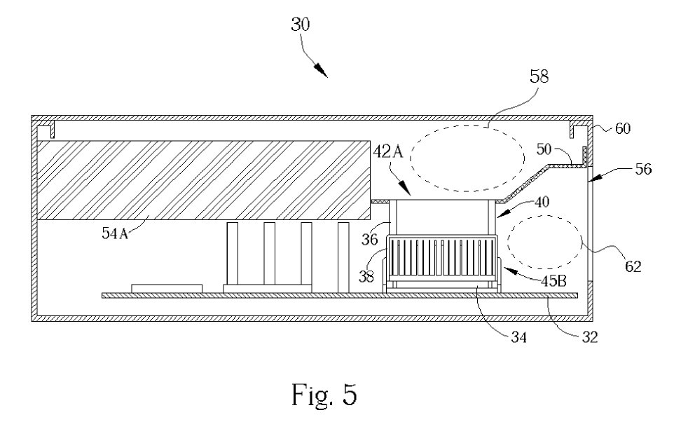

Please refer to FIG. 3 to FIG. 5 (also FIG. 2). FIG. 3 to FIG. 5 illustrate the heat sink module 40 installed in a computer system 30 having a case 60. For convenience, the case 60 is not shown in FIG. 4. FIG. 5 is a cross-sectional view along a line 5-5 of the computer system 30 in FIG. 3. Circuits of the computer system 30 are set on a motherboard 42 (in FIG. 4 and FIG. 5), and the cooling module 40 is set onto a circuit 34. The heat sink module 38 is attached to the circuit 34 for heat dissipation. The circuit 34 can be a system chip or a CPU of the computer system 30. Naturally, the computer system 30 can include other support devices (or peripherals) 54A, 54B. The support devices 54A and 54B can be power supplies, storage devices, hard disks, CD-ROMs, card readers or other add-on cards. In the present invention, the air wall 50 can fit all configurations of the support devices 54A and 54B, so that the air wall 50 can divide the computer system 30 into a cool zone 58 and a warm zone 62 (as shown in FIG. 5).

Moreover, the fan module 36 draws air from the cool zone 58, and blows air into the heat sink module 38, where heat is exchanged with the circuit 34. Then, heated air is exhausted from the air outlet 45B to the warm zone 62. Being isolated by the air wall 50, the warm zone 62 and the cool zone 58 don not have air cycling between them undesirably, so that heated air exhausted from the heat sink module 38 is prevented from flowing into the air inlet 42A of the fan module 36. Therefore, the present invention cooling module 40 can effectively dissipate heat. According to practical tests, the air wall 50 decreases air temperature at the air inlet 42A by 10%, and increases heat dissipation efficiency.

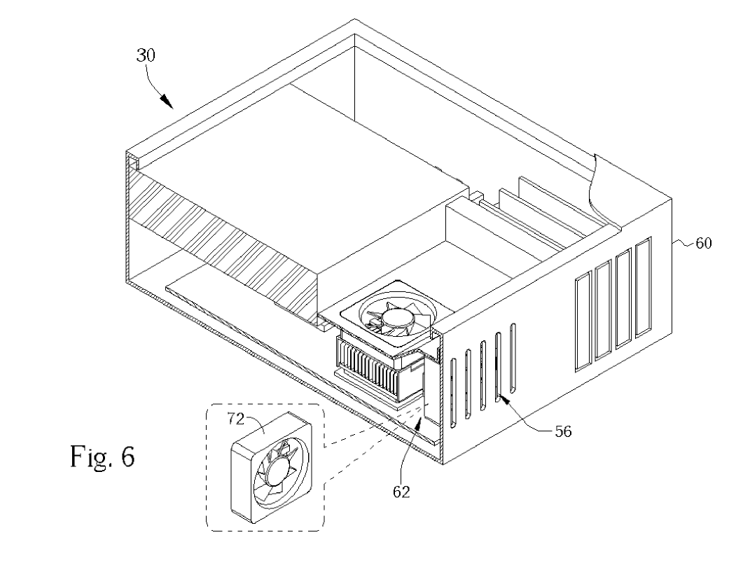

As FIG. 3 to FIG. 5 illustrate, holes 56 of the case 60 corresponding to the warm zone 62 can be further included in the computer system 30, so as to exhaust heated air from the warm zone 62 to outside of the computer system 30. Please refer to FIG. 6 (also FIG. 4). The computer system 30 can further include a fan module 72 corresponding to the holes 56 for forcibly exhausting heated air from the warm zone 62 to outside of the case 60.

In the present invention, the cool and warm zone 58 and 62 can be implemented by non-airtight configurations. That is, small spaces are allowed among the air wall 50, the case 60, and each support device for fabrication concerns, wire conduits, and the like.

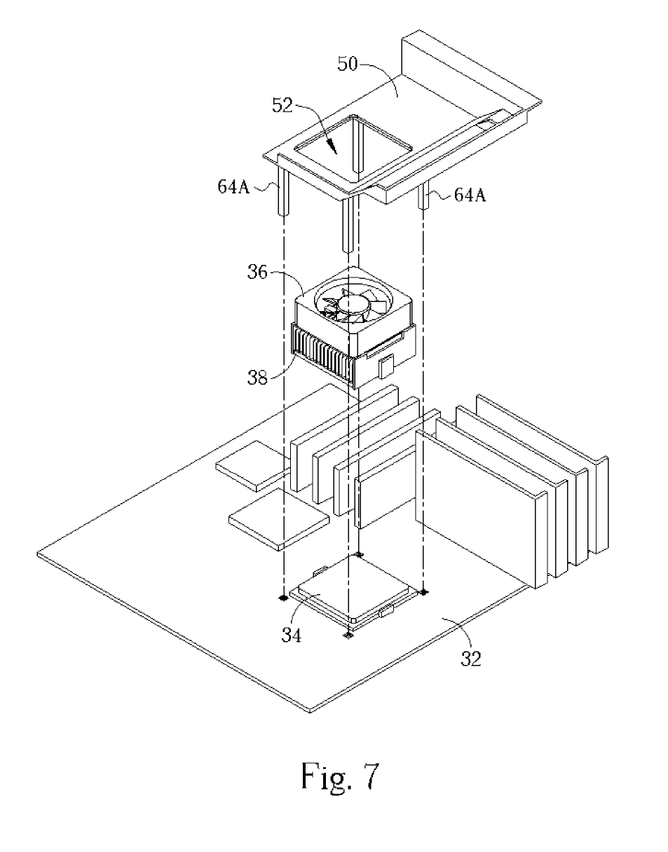

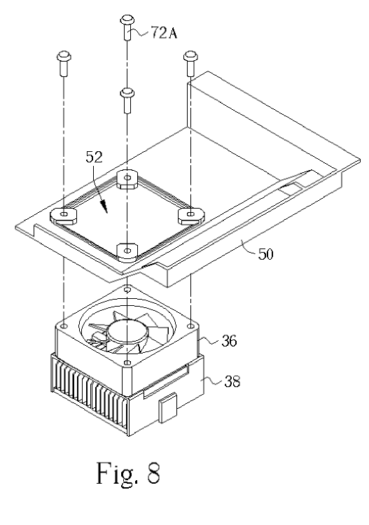

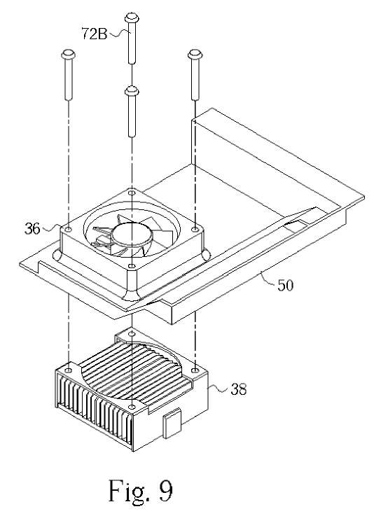

There are many ways to install the air wall 50 in the computer system 30. For example, please refer to FIG. 7, FIG. 8, and FIG. 9, which illustrate three configurations of the air wall 50. In FIG. 7, a pillar 64A is set in the bottom of the air wall 50, and can be fixed to the motherboard 32 with screws or hooks. In FIG. 8, the air wall 50 is set on the fan module 36 with screws 72A (or other mechanism such as latches). As shown in FIG. 9, the air wall 50 can be constructed in unison with the fan module 36. In this case, as long as the fan module 36 is set on the heat sink module 38 (with screws 72B for example), the cooling module 38 of the present invention is achieved with the air wall 50, and the approach 52 of the air wall 50 is also the air inlet of the heat sink module 38.

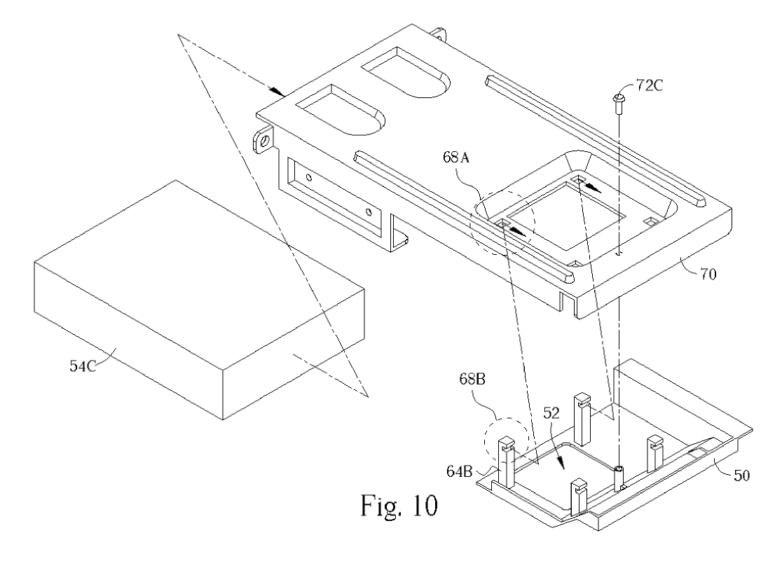

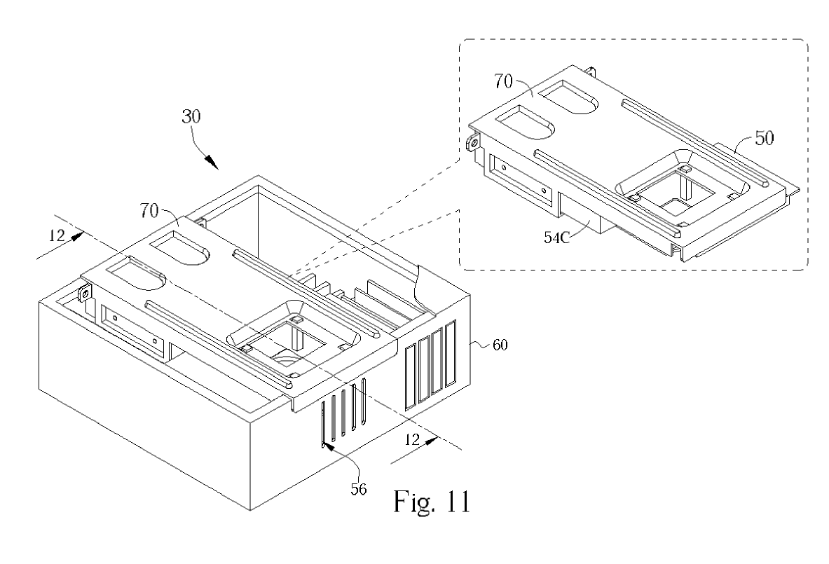

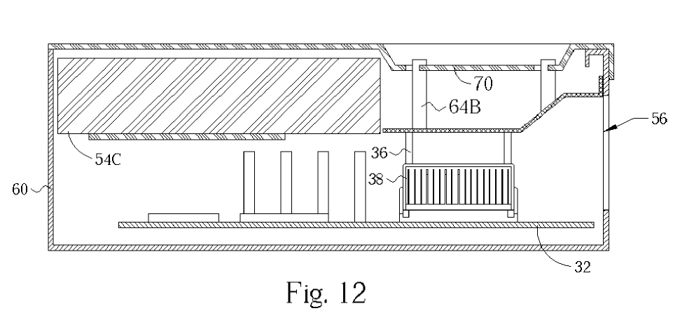

Please refer to FIG. 10 to FIG. 12. FIG. 10 illustrates the present invention air wall 50 constructed with a brace 70. FIG. 11 illustrates the brace 70 with the air wall 50 installed in the computer system 30. FIG. 12 illustrates a cross-sectional view along a line 12-12 in FIG. 11. As FIG. 10 illustrates, the present invention further includes a plurality of pillars 64B fixed to the air wall 50, where the top of each pillar 64B is a connection end 68B. Correspondingly, the brace 70 includes connection ends 68A, so that the air wall 50 can be fixed to the brace 70 with the connection ends 68B of the pillars 64B. In the present invention, the connection end 68B can be a hook, and the corresponding connection end 68A can be a latch in order that the air wall 50 can be easily fixed to the brace 70 by plugging in/out. Certainly, as illustrated in FIG. 10, the brace 70 and the air wall 50 further include corresponding holes for a screw 72C. In addition, other support devices 54C (such as hard disks, CD-ROMs, card readers, etc) can be installed in the brace 70.

As FIG. 11 illustrates, after the brace 70 with the air wall 50 is set into the case 60 of the computer system 30 (with latches or screws), the air wall 50 and the support devices 54C are set into the computer system 30 correspondingly. Please refer to FIG. 12. Besides fixing the air wall 50, the brace 70 can stiffen the case 60, so that the computer system 30 becomes more structurally stable. In addition, the brace 70 can contain support devices of the computer system 30, to make fabrication of the computer system 30 easier. In the present invention, the brace 70 with the fan module 36 and the heat sink module 38 can fit the current design as long as the approach 52 of the air wall 50 conforms to shape of the fan module 36 (or the heat sink module 38), so as to form an airway through the fan module 36.

In summary, the present invention isolates the air inlet of the fan module and the air outlet of the heat sink module with the air wall, so that heated air from the heat sink module is prevented from being recycled into the fan module. Therefore, the present invention cooling module has better heat dissipation efficiency than the prior art. Furthermore, the present invention can achieve the same heat dissipation efficiency as the prior art using a lower power and quieter fan. If the present invention uses the same power fan as in the prior art, the present invention achieves higher heat dissipation efficiency than the prior art, and further ensures normal operations of the computer system.

Those skilled in the art will readily observe that numerous modifications and alterations of the device may be made while retaining the teachings of the invention. Accordingly, the above disclosure should be construed as limited only by the metes and bounds of the appended claims.

1. A cooling module of a computer system comprising:
a fan module with an air inlet and an air outlet, capable of drawing air into the air inlet and exhausting air from the air outlet;
a heat sink module with an air inlet, an air outlet, and a heat conduction part; the heat conduction part being between the air inlet and the air outlet, the air inlet connecting to the air outlet of the fan module, the heat conduction part connecting to a circuit of the computer system; the heat sink module capable of drawing air into the air inlet and through the heat conduction part and exhausting air from the air outlet; and
an air wall between the air inlet of the fan module and the air outlet of the heat sink module for isolating airflow from the air outlet of the heat sink module to the air inlet of the fan module, so that heated air from the air outlet of the heat sink module is prevented from flowing into the air inlet of the fan module.

2. The cooling module of claim 1 wherein the air wall further comprises an approach; one end of the approach connecting to the air outlet of the fan module while another end connects to the air inlet of the heat sink module.

3. The cooling module of claim 1 and claim 2 wherein the computer system and the cooling module are disposed within a case.

4. The cooling module of claim 3 further comprising: a brace in the case; the air wall being fixed to the brace.

5. The cooling module of claim 4 wherein a support device of the computer system is capable of being fixed to the brace.

6. The cooling module of claim 4 wherein the air wall comprises at least one connection end while the brace comprises a corresponding connection end; the connection end of the air wall capable of plugging into the connection end of the brace.

7. The cooling module of claim 3 wherein the air wall divides the case into a first room and a second room, so that the fan module draws air from the first room, and the heat sink module exhausts air into the second room.

8. The cooling module of claim 7 further comprising: a second fan module in the case for exhausting air provided by the second room to outside the case.

9. The cooling module of claim 1 wherein the heat conduction part is connected to a central processing unit of the computer system.

10. A computer system comprising:
a case;
a circuit for controlling operations of the computer system; and
a cooling module in the case comprising:
a fan module with an air inlet and an air outlet, capable of drawing air into the air inlet and exhausting air from the air outlet;
a heat sink module with an air inlet, an air outlet, and a heat conduction part; the heat conduction part being between the air inlet and the air outlet, the air inlet connecting to the air outlet of the fan module, the heat conduction part connecting to the circuit; the heat sink module capable of drawing air into the air inlet and through the heat conduction part and exhausting air from the air outlet; and
an air wall between the air inlet of the fan module and the air outlet of the heat sink module for isolating airflow from the air outlet of the heat sink module to the air inlet of the fan module, so that heated air from the air outlet of the heat sink module is prevented from flowing into the air inlet of the fan module.

11. The computer system of claim 10 wherein the air wall further comprises an approach; one end of the approach connecting to the air outlet of the fan module while another end connects to the air inlet of the heat sink module.

12. The computer system of claim 10 further comprising: a brace in the case; the air wall being fixed to the brace.

13. The computer system of claim 12 further comprising a support device fixed to the brace for supporting operations of the computer system.

14. The computer system of claim 12 wherein the air wall comprises at least one connection end while the brace comprises a corresponding connection end; the connection end of the air wall capable of plugging into the connection end of the brace.

15. The computer system of claim 10 wherein the air wall divides the case into a first room and a second room, so that the fan module draws air from the first room, and the heat sink module exhausts air into the second room.

16. The computer system of claim 15 further comprising: a second fan module in the case for exhausting air provided by the second room to outside the case.

17. The computer system of claim 10 wherein the circuit is a central processing unit of the computer system.
